(19) United States
(12) Patent Application Publication
(10) Pub. No.: US 2018/0072564 A1
(43) Pub. Date: Mar. 15, 2018

(54) RESIN COMPOSITION FOR FORMING PHASE-SEPARATED STRUCTURE AND METHOD FOR PRODUCING STRUCTURE INCLUDING PHASE-SEPARATED STRUCTURE

(71) Applicants: TOKYO OHKA KOGYO CO., LTD., Kawasaki-shi (JP); NATIONAL UNIVERSITY CORPORATION HOKKAIDO UNIVERSITY, Sapporo-shi (JP)

(72) Inventors: Ken MIYAGI, Kawasaki-shi (JP); Takehiro SESHIMO, Kawasaki-shi (JP); Takaya MAEHASHI, Kawasaki-shi (JP); Takahiro DAZAI, Kawasaki-shi (JP); Hitoshi YAMANO, Kawasaki-shi (JP); Toshifumi SATOH, Sapporo-shi (JP); Takuya ISONO, Sapporo-shi (JP)

(21) Appl. No.: 15/653,318

(22) Filed: Jul. 18, 2017

(30) Foreign Application Priority Data
Sep. 13, 2016 (JP) 2016-179028

(51) Int. Cl. B81C 1/00; B05D 3/14; B05D 3/02; B05D 7/00; C08F 212/08; C08F 230/08; C08F 297/02

(52) U.S. Cl. CPC B81C 1/00031; B05D 3/148; B05D 3/02; B81C 2201/0149; C08F 212/08; C08F 230/08; C08F 297/026; B05D 7/56

(57) ABSTRACT

A resin composition for forming a phase-separated structure includes a block copolymer having a block (b1) having a repeating structure of styrene units; a block (b2) having a repeating structure of methyl methacrylate units partially substituted with a constituent unit represented by general formula (h1); and a number average molecular weight of less than 28,000. In general formula (h1), R^{h0} is a hydrophilic functional group.

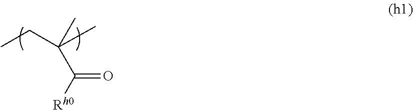

### BACKGROUND OF THE INVENTION

### Field of the Invention

The present invention relates to a resin composition for forming a phase-separated structure and a method for producing a structure including a phase-separated structure.

The present application claims priority based on Japanese Patent Application No. 2016-179028 filed on Sep. 13, 2016, and the contents of which are incorporated herein by reference.

### Background Art

In recent years, following further miniaturization of a large-scale integrated circuit (LSI), a technique for processing finer structures has been demanded.

For such a demand, there has been developed a technique for forming finer patterns by utilizing a phase-separated structure formed by the self-organization of the block copolymers in which incompatible blocks are bonded to each other (see, for example, Japanese Unexamined Patent Application, Publication No. 2008-36491).

In order to utilize the phase-separated structure of the block copolymer, it is essential to form the self-organized nanostructures, which are formed by microphase separation, only in a specific region and arrange the nanostructures in the desired direction. In order to realize these position control and orientation control, processes such as graphoepitaxy for controlling the phase separation pattern by the guide patterns and chemical epitaxy for controlling the phase separation pattern by the difference in the chemical state of the substrate have been proposed (See, for example, Proceedings of SPIE, Vol. 7637, No. 76370G-1, 2010).

The block copolymer forms a structure having a regular periodic structure by the phase separation.

The “period of a structure” means the period of the phase structure observed when the structure of a phase-separated structure is formed and refers to the sum of the lengths of the respective phases incompatible with each other. In a case where the phase-separated structure forms a cylinder structure perpendicular to the substrate surface, the period (L0) of the structure is the center-to-center distance (pitch) between two adjacent cylinder structures.

It is known that the period (L0) of the structure is determined by inherent polymerization properties such as the degree of polymerization N and interaction parameter χ of Flory-Huggins. That is, the larger the product “χ·N” of χ and N is, the greater the mutual repulsion between the different blocks in the block copolymer becomes. Therefore, in a case of the relation of χ·N>10 (hereinafter, referred to as “strong separation limit”), the repulsion between the different kinds of blocks in the block copolymer is large, and the tendency for phase separation to occur becomes strong. Accordingly, in the strong separation limit, the period of the structure is approximately N^{2/3}·χ^{1/6}, and satisfies the relationship of the following equation (1). That is, the period of the structure is proportional to the degree of polymerization N, which correlates with the molecular weight and the molecular weight ratio between the different blocks.

L0∝a·N^{2/3}·χ^{1/6} (1)

(In the equation, L0 represents the period of the structure. a is a parameter indicating the size of the monomer. N represents a degree of polymerization. χ is an interaction parameter, and the higher the value thereof, the higher the phase separation performance.)

Accordingly, the period (L0) of the structure can be controlled by adjusting the composition and the total molecular weight of the block copolymer.

It is known that the periodic structure which the block copolymer forms varies the form such as a cylinder (columnar phase), a lamella (plate phase), and a sphere (spherical phase) depending on the volume ratio of the polymer components, and the period depends on the molecular weight. Therefore, a method for increasing the molecular weight of the block copolymers can be considered in order to form the structure of a relatively large period (L0) by utilizing the phase-separated structure formed by the self-organization of the block copolymers.

It is also conceivable to use a method for using a block copolymer having a larger interaction parameter (χ) than that of a block copolymer having a block of styrene and a block of methylmethacrylate, which is a general-purpose block copolymer. For example, JP-T-2014-521790 proposes a composition including a block copolymer in which approximately 50% to 90% of a polyisoprene block of a poly(styrene-b-isoprene) block copolymer has been modified with an epoxy functional group.

### SUMMARY OF THE INVENTION

However, at present, it is difficult to further improve the phase separation performance in forming a structure by utilizing a phase-separated structure formed by the self-organization of a block copolymer having a block of styrene and a block of methyl methacrylate, which is a general-purpose block copolymer.

In the composition described in PCT Japanese Translation Patent, Publication No. 2014-521790, a new monomer (isoprene) is required for producing the block copolymer. With the adoption of this new monomer, it is necessary to set new reaction conditions in order to achieve the narrow distribution of the block copolymer.

The present invention has been made in view of the above circumstances, and an object of the invention is to provide a method for producing a structure including a phase-separated structure, which can further improve the phase separation performance without requiring a new monomer, and a resin composition for forming a phase-separated structure, which can be used therefor.

The present inventors have found a method for making a larger difference in hydrophilicity/hydrophobicity between the hydrophobic block portion and the hydrophilic block portion in the phase-separated structure larger by using a block copolymer (PS-b-PMMA) having a block of styrene and a block of methyl methacrylate, which is a general-purpose block copolymer, without requiring a new monomer besides styrene and methylmethacrylate, thereby completing the present invention.

That is, a first aspect of the invention is a resin composition for forming a phase-separated structure including a block copolymer having a block (b1) having a repeating structure of styrene units and a block (b2) having a repeating structure of methyl methacrylate units partially substituted with a constituent unit represented by the following general Formula (h1) and a number average molecular weight of less than 28,000.

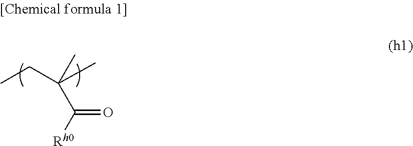

In the Formula, R^{h0} is a hydrophilic functional group.

A second aspect of the invention is a method for producing a structure including a phase-separated structure including: a step of applying a resin composition for forming a phase-separated structure according to the first aspect on a support to form a layer including a block copolymer; and a step of phase-separating the layer including the block copolymer.

According to the invention, it is possible to provide a method for producing a structure including a phase-separated structure, which can further improve the phase separation performance without requiring a new monomer, and a resin composition for forming a phase-separated structure which can be used therefor.

### BRIEF DESCRIPTION OF THE DRAWINGS

FIG. 1 is a schematic process diagram illustrating an example of an embodiment of a method for producing a structure including a phase-separated structure.

FIG. 2 is a diagram for explaining an example of an embodiment of an optional step.

FIG. 3 is a diagram showing X-ray small angle scattering (SAXS) patterns of a phase-separated structure formed by using the resin composition of each example.

### DETAILED DESCRIPTION OF THE INVENTION

In this specification and claims, the term “aliphatic” is defined as a relative concept to aromatic, and means a group, a compound, and the like having no aromaticity.

Unless otherwise specified, the term “alkyl group” is intended to include linear, branched, and cyclic monovalent saturated hydrocarbon groups.

The term “constituent unit” means a monomer unit for constituting a polymer compound (resin, polymer, and copolymer).

The case where it is described as “may have a substituent” includes both a case where a hydrogen atom (—H) is substituted with a monovalent group and a case where a methylene group (—CH₂—) is substituted with a divalent group.

The term “exposure” is a concept including irradiation with radiation as a whole.

### Resin Composition for Forming Phase-Separated Structure

A resin composition for forming a phase-separated structure of the embodiment includes a block copolymer having a block (b1) having a repeating structure of styrene units; a block (b2) having a repeating structure of methyl methacrylate units partially substituted with a constituent unit represented by general formula (h1); and a number average molecular weight of less than 28,000 (hereinafter, also referred to as “(BCP) component”).

### Block Copolymer

A block copolymer ((BCP) component) of the embodiment includes a block (b1) having a repeating structure of styrene units and a block (b2) having a repeating structure of methyl methacrylate units partially substituted with a constituent unit represented by general formula (h1), and has a number average molecular weight of less than 28,000.

The number average molecular weight (Mn) (based on polystyrene conversion by gel permeation chromatography (GPC)) of the (BCP) component is less than 28,000, preferably 25,000 or less, more preferably 5,000 to 25,000, and still more preferably 15,000 to 20,000.

If the Mn of the (BCP) component is less than the upper limit of the above range, the phase separation performance is enhanced and a phase-separated structure with a period shorter than 24 nm, for example, can be formed. On the other hand, if the Mn is equal to or greater than the lower limit of the preferable range, the phase-separated structure can be stably formed.

### Block (b1)

The block (b1) consists of a repeating structure of the styrene units.

As the styrene unit, a constituent unit represented by the following general formula (b1-1) can be exemplified.

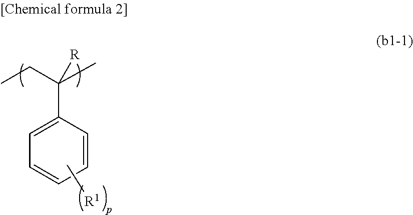

In the formula, R is a hydrogen atom or a methyl group. R¹ is an alkyl group having 1 to 5 carbon atoms. p is an integer of 0 to 5.

In the formula (b1-1), R¹ is an alkyl group having 1 to 5 carbon atoms, preferably an alkyl group having 1 to 4 carbon atoms, and more preferably a methyl group or an ethyl group.

In the formula (b1-1), p is an integer of 0 to 5, preferably an integer of 0 to 3, more preferably 0 or 1, and particularly preferably 0.

### Block (b2)

The block (b2) consists of a repeating structure of methyl methacrylate units partially substituted with a constituent unit represented by the following general formula (h1).

Hereinafter, the methyl methacrylate unit is also referred to as a “constituent unit (b21)” and the constituent unit represented by general formula (h1) is referred to as a “constituent unit (b22)”.

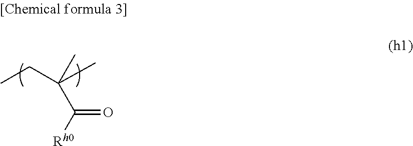

(In the formula, R^{h0} is a hydrophilic functional group.)

In the formula (h1), R^{h0} is a hydrophilic functional group.

The hydrophilic functional group represented by R^{h0} may be any functional group that increases the hydrophilicity of the monomer for inducing the constituent unit (b22) as compared with the hydrophilicity of methyl methacrylate, and in particular, preferably a hydrophilic functional group derived from an amine.

Examples of the hydrophilic functional group derived from an amine as R^{h0} include functional groups represented by the following general formula (R^{h0}-1)

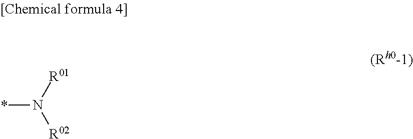

In the formula, R⁰¹ is an aliphatic hydrocarbon group having at least —OH as a substituent. R⁰² is an aliphatic hydrocarbon group which may have a substituent or a hydrogen atom. * is a bonding site that bonds to the carbon atom of the carbonyl group in the formula (h1).

In the formula (R^{h0}-1), R⁰¹ is an aliphatic hydrocarbon group having at least —OH as a substituent.

The aliphatic hydrocarbon group in R⁰¹ may be chain-like or cyclic, and is preferably chain-like. The aliphatic hydrocarbon group in R⁰¹ may be linear or branched, and is preferably linear.

The aliphatic hydrocarbon group (having no substituent) in R⁰¹ is preferably an alkyl group having 1 to 8 carbon atoms, more preferably an alkyl group having 1 to 5 carbon atoms, and still more preferably an alkyl group having 1 to 3 carbon atoms.

Examples of the substituent for substituting a hydrogen atom bonded to an aliphatic hydrocarbon group in R⁰¹ include an alkoxy group and the like, in addition to a hydroxyl group.

In the formula (R^{h0}-1), R⁰² is an aliphatic hydrocarbon group which may have a substituent or a hydrogen atom.

Examples of the aliphatic hydrocarbon group in R⁰² include the same group as aliphatic hydrocarbon groups (having no substituent) in the above-mentioned R⁰¹.

Examples of the substituent for substituting the hydrogen atom bonded to the aliphatic hydrocarbon group in R⁰² include a hydroxyl group, an alkoxy group, and the like.

Specific examples of R^{h0} (a hydrophilic functional group) are shown below.

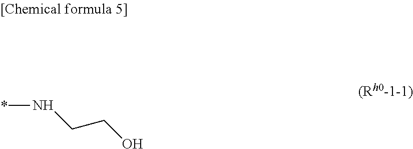 [SMILES: *NCCO]

The proportion of the constituent unit (b22) in the (BCP) component is preferably 1 to 10 mol %, more preferably 1 to 5 mol %, and still more preferably 1 to 3 mol % with respect to the total constituent units (100 mol %) constituting the (BCP) component.

If the proportion of the constituent unit (b22) is equal to or greater than the lower limit of the above-mentioned preferable range, a phase-separated structure with a shorter period is more likely to be formed. On the other hand, if the proportion is equal to or less than the upper limit of the above-mentioned preferable range, the hydrophilicity of the block (b2) does not become too high, and the phase-separated structure between the hydrophobic block (b1) and the hydrophilic block (b2) tends to be stably formed.

The proportion of the constituent unit (b22) in the block (b2) is preferably 0.5 mol % or more, more preferably 0.5 to 2.5 mol %, and still more preferably 0.5 to 1.5 mol % with respect to the total constituent units (100 mol %) constituting the block (b2).

If the proportion of the constituent unit (b22) is equal to or greater than the lower limit of the above-mentioned preferable range, a phase-separated structure with a shorter period is more likely to be formed. On the other hand, if the proportion is equal to or less than the upper limit of the above-mentioned preferable range, the hydrophilicity of the block (b2) is suppressed to an appropriate level.

The proportion of the constituent unit (b22) in the block (b2) can be controlled by the time of reaction between the block copolymer in the step (p2) described later and the compound having the hydrophilic functional group (R^{h0}).

The block copolymer (the (BCP) component) of the embodiment can be produced, for example, by a production method including the following steps.

Step (p1): a step of polymerizing styrene and methyl methacrylate to obtain a block copolymer (PS-b-PMMA)

Step (p2): a step of reacting the obtained block copolymer with a compound having a hydrophilic functional group (R^{h0})

### Step (p1):

Since the polymerization of styrene and methyl methacrylate can easily obtain a block copolymer (PS-b-PMMA), living polymerization is preferable. As a preferred living polymerization method, living anionic polymerization and living radical polymerization can be exemplified, and living anionic polymerization is particularly preferable since the narrow distribution can be further achieved.

### Step (p2):

The compound having a hydrophilic functional group (R^{h0}) may be a compound capable of introducing a hydrophilic functional group (R^{h0}) into the “—OCH₃” site of a methyl methacrylate unit, and examples thereof include monoethanolamine, ethylene glycol, and the like.

The temperature of the reaction between the block copolymer obtained in the step (p1) and the compound having a hydrophilic functional group (R^{h0}) is preferably 50 to 150° C. and more preferably 80 to 120° C.

The time of the reaction between the block copolymer obtained in the step (p1) and the compound having a hydrophilic functional group (R^{h0}) is preferably 1 to 18 hours and more preferably 6 to 12 hours.

According to the production method including the step (p1) and the step (p2), the (BCP) component in which the narrow distribution is achieved and the difference in hydrophilicity/hydrophobicity between the hydrophobic block portion and the hydrophilic block portion in the block copolymer is made larger can be conveniently obtained.

For example, the (BCP) component in which the molecular weight distribution (Mw/Mn) is preferably 1.01 to 1.10, more preferably 1.01 to 1.05, and still more preferably 1.01 to 1.02 can be easily obtained. Mw represents the mass average molecular weight.

### Organic Solvent Component

The resin composition for forming a phase-separated structure of the embodiment can be prepared by dissolving the (BCP) component in an organic solvent component.

Any organic solvent component may be used as long as it can dissolve the respective components to be used and form a homogeneous solution, and arbitrary solvents may be selected from any solvents known in the related art as a solvent for a film composition including a resin as a main component.

Examples of the organic solvent component include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; a compound having an ester bond such as ethylene glycol monoacetate, diethylene glycol monoacetate, propylene glycol monoacetate, and dipropylene glycol monoacetate; derivatives of polyhydric alcohols such as compounds having an ether bond such as monoalkyl ethers such as monomethyl ether, monoethyl ether, monopropyl ether, and monobutyl ether or monophenyl ether of the polyhydric alcohols or compounds having an ester bond [among these, propylene glycol monomethyl ether acetate (PGMEA) and propylene glycol monomethyl ether (PGME) are preferable]; cyclic ethers such as dioxane, or esters such as methyl lactate, ethyl lactate (EL), methyl acetate, ethyl acetate, butyl acetate, methyl pyruvate, ethyl pyruvate, methyl methoxy propionate, and ethyl ethoxy propionate; aromatic organic solvents such as anisole, ethyl benzyl ether, cresyl methyl ether, diphenyl ether, dibenzyl ether, phenetole, butyl phenyl ether, ethyl benzene, diethyl benzene, pentyl benzene, isopropyl benzene, toluene, xylene, cymene, and mesitylene.

The organic solvent component may be used alone or as a mixed solvent of two or more kinds thereof. Among these, propylene glycol monomethyl ether acetate (PGMEA), propylene glycol monomethyl ether (PGME), cyclohexanone, and EL are preferable.

A mixed solvent which is obtained by mixing PGMEA and a polar solvent is also preferable. The blending ratio (mass ratio) may be appropriately determined in consideration of compatibility between PGMEA and the polar solvent, and it is preferably in a range of 1:9 to 9:1 and more preferably 2:8 to 8:2.

For example, in a case where EL is blended as a polar solvent, the mass ratio of PGMEA:EL is preferably 1:9 to 9:1 and more preferably 2:8 to 8:2. In a case where PGME is blended as the polar solvent, the mass ratio of PGMEA:PGME is preferably 1:9 to 9:1, more preferably 2:8 to 8:2, and still more preferably 3:7 to 7:3. In a case where PGME and cyclohexanone are blended as a polar solvent, the mass ratio of PGMEA:(PGME+cyclohexanone) is preferably 1:9 to 9:1, more preferably 2:8 to 8:2, and still more preferably 3:7 to 7:3.

As the organic solvent component in the resin composition for forming a phase-separated structure, in addition to those components, a mixed solvent in which PGMEA, EL, or the mixed solvent of PGMEA and a polar solvent is mixed with γ-butyrolactone is also preferable. In this case, the mass ratio of the former to the latter is, as the mixing ratio, preferably 70:30 to 95:5.

The concentration of the organic solvent component included in the resin composition for forming a phase-separated structure is not particularly limited, and the component is appropriately set at a concentration with which the coating can be performed according to the coating film thickness. The solid content concentration is generally used in a range of 0.2 to 70 mass % and preferably in a range of 0.2 to 50 mass %.

### Optional Component

The resin composition for forming a phase-separated structure may appropriately include, if desired, miscible additives such as additional resins for improving the layer performance, surfactants for improving coatability, a dissolution inhibitor, a plasticizer, a stabilizer, a colorant, a halation inhibitor, a dye, a sensitizer, a base proliferating agent, and a basic compound, in addition to the above-mentioned (BCP) component and the organic solvent component.

The resin composition for forming a phase phase-separated structure according to the above-described embodiment has a block (b1) and a block (b2) and includes a block copolymer (the (BCP) component) having a number average molecular weight of less than 28,000. Since the block copolymer has the block (b1) and the block (b2), the block copolymer does not require new monomers other than styrene and methyl methacrylate, and thus the difference in hydrophilicity/hydrophobicity between the hydrophobic block portion (the block (b1)) and the hydrophilic block portion (the block (b2)) in the phase-separated structure is larger than the difference in hydrophilicity/hydrophobicity between the block of styrene units and the block of methyl methacrylate units. In addition, the number average molecular weight of the block copolymer is kept as low as less than 28,000. Accordingly, the repulsion between the block (b1) and the block (b2) is increased, that is, the value of the interaction parameter (χ) becomes larger, and the phase separation performance is further enhanced.

In addition, the (BCP) component in the embodiment can achieve high polarity by using a block copolymer (PS-b-PMMA) having a block of styrene unit and a block of methyl methacrylate unit already synthesized in a narrow distribution state by living anionic polymerization and the like and then by partially substituting the PMMA. Accordingly, it is possible to use a block copolymer which maintains a narrow distribution state and has an increased difference in hydrophilicity/hydrophobicity. As a result, the phase separation performance is further enhanced.

Another embodiment of the resin composition for forming a phase-separated structure includes a resin composition including a block copolymer having a block (b1) having a repeating structure of styrene units and a block (b2) having a repeating structure of methyl methacrylate units partially substituted with a constituent unit represented by general formula (h1).

The number average molecular weight (Mn) (based on polystyrene conversion by GPC) of the block copolymer in such another embodiment is preferably less than 28,000, more preferably 25,000 or less, still more preferably 5,000 to 25,000, and particularly preferably 15,000 to 20,000.

The description of methods for producing the block (b1), the block (b2), and the block copolymer is the same as the above-described methods for producing the block (b1), the block (b2), and the block copolymer.

The resin composition for forming a phase-separated structure of another embodiment can be prepared by dissolving a block copolymer in an organic solvent component. Examples of the organic solvent component include the same ones as the above “Organic Solvent Component”.

In addition, the resin composition for forming a phase-separated structure of another embodiment may appropriately include, if desired, miscible additives such as additional resins for improving layer performance, surfactants for improving coatability, a dissolution inhibitor, a plasticizer, a stabilizer, a colorant, a halation inhibitor, a dye, a sensitizer, a base proliferating agent, and a basic compound, in addition to the block copolymer and the organic solvent component.

In the resin composition for forming a phase-separated structure of such another embodiment, a block copolymer which maintains a state of narrow distribution and increases the difference in hydrophilicity/hydrophobicity as described above is used. As a result, the phase separation performance can be further enhanced. According to the resin composition for forming a phase-separated structure of another embodiment, a microstructure having a conventional cycle of 23 to 24 nm or even shorter cycle than the conventional cycle can be produced by using a block copolymer having a lower molecular weight than that of the conventional resin composition.

### Method for Producing Structure Including Phase-Separated Structure

The method for producing a structure including a phase-separated structure according to the embodiment includes a step of applying a resin composition for forming a phase-separated structure of the above embodiment on a support to form a layer including a block copolymer (hereinafter, referred to as “step (i)”) and a step of phase-separating layer including the block copolymer (hereinafter, referred to as “step (ii)”).

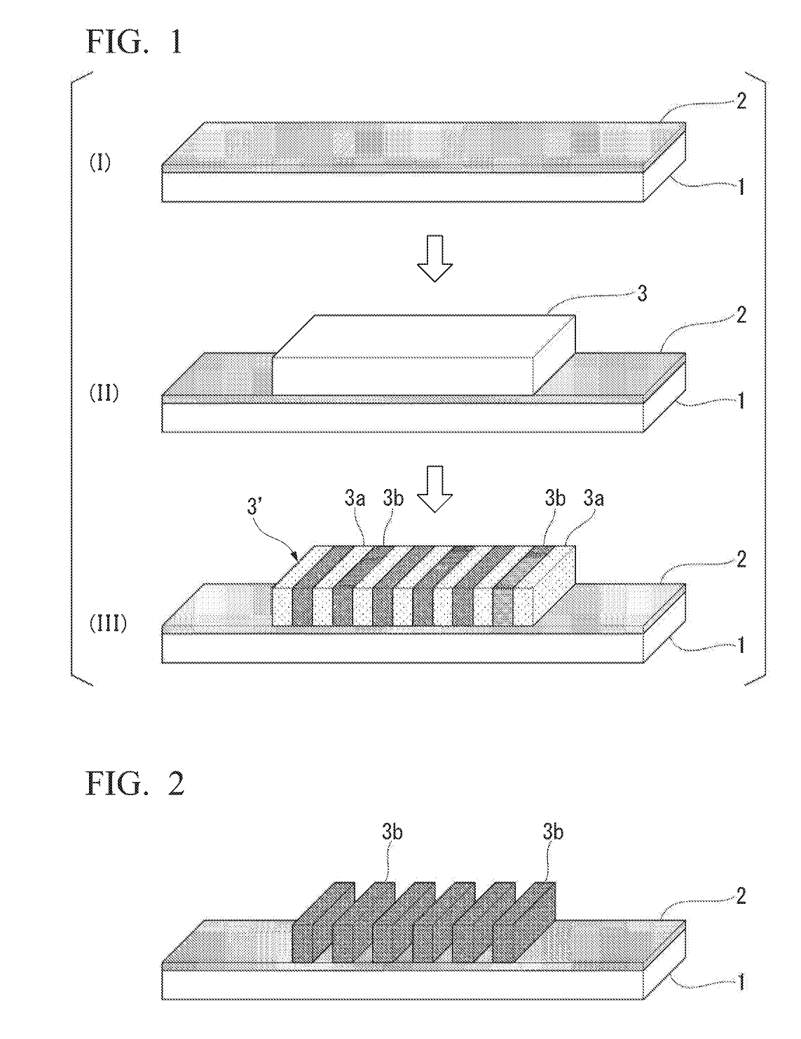

Hereinafter, a method for producing a structure including such a phase-separated structure will be described in detail with reference to FIG. 1. However, the present invention is not limited thereto.

FIG. 1 shows an embodiment of a method for producing a structure including a phase-separated structure.

In the embodiment shown in FIG. 1, first, an undercoat agent layer 2 is formed by applying an undercoat agent on a support 1 (FIG. 1 (I)).

Next, the layer (BCP layer) 3 including the (BCP) component is formed by applying the resin composition for forming a phase-separated structure of the above-described embodiment on the undercoat agent layer 2 (FIG. 1 (II); the above, step (i)).

Next, the BCP layer 3 is phase-separated into the phase 3a and the phase 3b by heating and annealing treatment (FIG. 1 (III); step (ii)).

According to the production method of this embodiment, that is, the production method including the step (i) and the step (ii), the structure 3′ including the phase-separated structure is produced on the support 1 on which the undercoat agent layer 2 is formed.

### Step (i)

In the step (i), the BCP layer 3 is formed by applying a resin composition for forming a phase-separated structure on the support 1.

In the embodiment shown in FIG. 1, first, the undercoat agent layer 2 is formed by applying the undercoat agent on the support 1.

By providing the undercoat agent layer 2 on the support 1, a hydrophilic/hydrophobic balance between the surface of the support 1 and the layer (BCP layer) 3 including the block copolymer can be achieved.

That is, in a case where the undercoat agent layer 2 includes a resin component having the constituent unit constituting the block (b1), the adhesiveness between the phase having the block (b1) of the BCP layer 3 and the support 1 is enhanced. In a case where the undercoat agent layer 2 includes a resin component having the constituent unit constituting the block (b2), the adhesiveness between the phase having the block (b2) of the BCP layer 3 and the support 1 is enhanced.

Accordingly, a cylinder structure oriented in the direction perpendicular to the surface of the support 1 is likely to be formed due to the phase separation of the BCP layer 3.

### Undercoat Agent:

A resin composition can be used as an undercoat agent.

The resin composition for the undercoat agent can be appropriately selected from the resin compositions known in the related art used for forming a thin film depending on the type of the block constituting the (BCP) component.

The resin composition for the undercoat agent may be, for example, a thermopolymerizable resin composition or may be a photosensitive resin composition such as a positive-type resist composition or a negative-type resist composition. A non-polymerizable film formed by applying a compound being a surface treatment agent may be used as an undercoat agent layer. For example, a siloxane-based organic monomolecular film formed by applying phenethyltrichlorosilane, octadecyltrichlorosilane, hexamethyldisilazane, or the like as a surface treating agent can also be suitably used as an undercoat agent layer.

Examples of such a resin composition include a resin composition including a resin having any of the constituent units constituting each of the block (b1) and the block (b2), a resin composition including a resin having both each block constituting the (BCP) component and a constituent unit having a high affinity, and the like.

As a resin composition for the under coat agent, for example, a composition including a resin having both styrene and methyl methacrylate as a constituent unit and a compound or a composition including both a site having a high affinity with styrene such as an aromatic ring and a site having a high affinity with methyl methacrylate (such as a highly polar functional group) are preferably used.

As a resin having both styrene and methyl methacrylate as a constituent unit, a random copolymer of styrene and methyl methacrylate, an alternating polymer of styrene and methyl methacrylate (the polymer in which each monomer is alternately copolymerized), and the like can be exemplified.

In addition, as a composition including both a site having a high affinity with styrene and a site having a high affinity with methyl methacrylate, for example, a composition having a resin obtained by polymerizing at least, as a monomer, a monomer having an aromatic ring and a monomer having a high polarity functional group can be exemplified. As the monomer having an aromatic ring, a monomer having an aryl group obtained by removing a hydrogen atom from an aromatic hydrocarbon ring, such as a phenyl group, a biphenyl group, a fluorenyl group, a naphthyl group, an anthryl group, and a phenanthryl group, or a heteroaryl group in which carbon atoms constituting the ring of these groups are partially substituted with a hetero atom such as an oxygen atom, a sulfur atom or a nitrogen atom can be exemplified. In addition, as a monomer having a highly polar functional group, a monomer having a trimethoxysilyl group, a trichlorosilyl group, an epoxy group, a glycidyl group, a carboxyl group, a hydroxyl group, a cyano group, a hydroxyalkyl group in which the hydrogen atoms of the alkyl group are partially substituted with a hydroxyl group, and the like can be exemplified.

Further, as a compound including both a site having a high affinity with styrene and a site having a high affinity with methyl methacrylate, a compound including both an aryl group such as phenethyltrichlorosilane and a highly polar functional group, or a compound including both an alkyl group such as an alkylsilane compound and a highly polar functional group, and the like can be exemplified.

The resin composition for the undercoat agent can be produced by dissolving the above-mentioned resin in a solvent.

As such a solvent, any solvent may be used as long as it can dissolve the respective components to be used and form a homogeneous solution. For example, the same organic solvent components as exemplified in the description of the resin composition for forming a phase-separated structure of the above-described embodiment can be exemplified.

The type of the support 1 is not particularly limited as long as the resin composition can be applied on its surface. For example, a substrate made of an inorganic material such as a metal (silicon, copper, chromium, iron, and aluminum), glass, titanium oxide, silica or mica; a substrate made of an oxide such as SiO₂; a substrate made of a nitride such as SiN; a substrate made of an oxynitride such as SiON; and a substrate made of an organic material such as acryl, polystyrene, cellulose, cellulose acetate, phenolic resin, and the like can be exemplified. Among these, a metal substrate is preferable, and for example, a structure of a cylinder structure is likely to be formed in a silicon substrate (Si substrate) or a copper substrate (Cu substrate). Among these, a Si substrate is particularly preferable.

The size and shape of the support 1 are not particularly limited. The support 1 is not necessarily required to have a smooth surface, and substrates of various shapes can be appropriately selected. For example, a substrate having a curved surface, a flat surface having an uneven surface, and a substrate with flaky shape can be exemplified.

An inorganic and/or organic film may be provided on the surface of the support 1.

As an inorganic film, an inorganic antireflection film (inorganic BARC) can be exemplified. As an organic film, an organic antireflection film (organic BARC) can be exemplified.

The inorganic film can be formed, for example, by applying an inorganic antireflection film composition such as a silicon-based material on a support and by baking the film, and the like.

For example, the organic film is formed by applying a material for forming an organic film in which a resin component constituting the film is dissolved in an organic solvent on a substrate using a spinner or the like and by baking the film under heating conditions of preferably 200 to 300° C., preferably for 30 to 300 seconds and more preferably for 60 to 180 seconds. The material for forming this organic film does not necessarily need to have sensitivity to light or electron beams such as a resist film, and may or may not have sensitivity. Specifically, a resist or a resin generally used for the production of a semiconductor element or a liquid crystal display element can be used.

In addition, it is preferable that the material for forming an organic film is a material capable of forming an organic film which can be subjected to etching, particularly dry-etched so that the organic film can be etched through the pattern which is made of the block copolymer, formed by processing the BCP layer 3 and the pattern can be transferred on the organic film to form an organic film pattern. Among these, a material capable of forming an organic film capable of being subjected to etching such as oxygen plasma etching is preferable. Such a material for forming an organic film may be a material used for forming an organic film such as organic BARC in the related art. For example, the ARC series manufactured by NISSAN CHEMICAL INDUSTRIES, LTD., the AR series manufactured by Rohm and Haas Japan Ltd., and the SWK series manufactured by TOKYO OHKA KOGYO CO., LTD. and the like can be exemplified.

The method for forming the undercoat agent layer 2 by applying the undercoat agent on the support 1 is not particularly limited and the undercoat agent layer 2 can be formed by a known method in the related art.

For example, the undercoat agent layer 2 can be formed by applying the undercoat agent on the support 1 by a known method in the related art such as using a spin coating or a spinner to form a coating film, and drying the coating film.

As a method for drying the coating film, any method for drying the coating film may be used as long as the solvent included in the undercoat agent can be volatilized, and for example, a method for baking the coating film can be exemplified. In this case, the baking temperature is preferably 80 to 300° C., more preferably 180 to 270° C., and still more preferably 220 to 250° C. The baking time is preferably 30 to 500 seconds and more preferably 60 to 400 seconds.

The thickness of the undercoat agent layer 2 after drying the coating film is preferably about 10 to 100 nm and more preferably about 40 to 90 nm.

The surface of the support 1 may be cleaned in advance before forming the undercoat agent layer 2 on the support 1. The coatability of the undercoat agent is improved by cleaning the surface of the support 1.

As the cleaning treatment method, known methods in the related art can be used, and examples thereof include oxygen plasma treatment, ozone oxidation treatment, acid alkali treatment, chemical modification treatment, and the like.

After the undercoat agent layer 2 is formed, the undercoat agent layer 2 may be rinsed with a rinsing liquid such as a solvent, if necessary. Since the uncrosslinked portion of the undercoat agent layer 2 is removed by the rinsing, the affinity with at least one block constituting the block copolymer is improved, and therefore, a phase-separated structure having a cylinder structure oriented in the direction perpendicular to the surface of the support 1 is likely to be formed.

The rinsing liquid may be anyone as long as it can dissolve the uncrosslinked portion and may be a solvent such as propylene glycol monomethyl ether acetate (PGMEA), propylene glycol monomethyl ether (PGME), ethyl lactate (EL) or a commercially available thinner liquid.

After the cleaning, post-baking may be performed in order to volatilize the rinsing liquid. The temperature condition of the post-baking is preferably from 80 to 300° C., more preferably from 100 to 270° C., and still more preferably from 120 to 250° C. The baking time is preferably 30 to 500 seconds and more preferably 60 to 240 seconds. The thickness of the undercoat agent layer 2 after such post-baking is preferably about 1 to 10 nm and more preferably about 2 to 7 nm.

Next, the layer (BCP layer) 3 including the (BCP) component is formed on undercoat agent layer 2.

The method for forming the BCP layer 3 on the undercoat agent layer 2 is not particularly limited. For example, a method for forming the coating film by applying a resin composition for forming a phase-separated structure of the above-described embodiment on the undercoat agent layer 2 by a known method in the related art such as using a spin coating or a spinner to form a coating film and by drying the coating film can be exemplified.

The thickness of the BCP layer 3 may be a thickness sufficient to cause phase separation, and the thickness is preferably from 20 to 100 nm and more preferably from 30 to 80 nm, in consideration of the type of the support 1, the structure period size of the phase-separated structure to be formed, or the uniformity of the nanostructure.

For example, in a case where the support 1 is a Si substrate, the thickness of the BCP layer 3 is preferably adjusted to 10 to 100 nm and more preferably 30 to 80 nm.

### Step (ii)

In the step (ii), the BCP layer 3 formed on the support 1 is phase-separated.

By heating to perform an annealing treatment of the support 1 after step (i), a phase-separated structure is formed so that at least a part of the surface of the support 1 is exposed by selective removal of the block copolymer. That is, a structure 3′ including a phase-separated structure which is phase-separated into a phase 3a and a phase 3b is produced on the support 1.

The annealing treatment is preferably performed under the temperature condition of being equal to or higher than the glass transition temperature of the (BCP) component used and lower than the thermal decomposition temperature. For example, in a case where the block copolymer is polystyrene-polymethyl methacrylate (PS-PMMA) block copolymer (Mass average molecular weight of 5,000 to 100,000), the temperature is preferably 180 to 270° C. The heating time is preferably 30 to 3,600 seconds.

In addition, it is preferable that the annealing treatment can be performed in a gas having low reactivity such as nitrogen.

According to the method for producing a structure including a phase-separated structure of the embodiment described above, since the resin composition for forming a phase-separated structure of the above-described embodiment is used, the phase separation performance of the block copolymer is enhanced and a finer structure can be formed in a good shape as compared with the case of using a block copolymer (PS-b-PMMA) having a block of styrene and a block of methyl methacrylate which is a general-purpose block copolymer.

In addition, according to the method for producing a structure including a phase-separated structure of the embodiment, it is possible to produce a support having nanostructures whose positions and orientations are more freely designed on the surface of the support. For example, the structure to be formed has a high adhesiveness with the support and is likely to take a phase-separated structure having a cylinder structure oriented in the direction perpendicular to the surface of the support.

### Optional Step

The method for producing a structure including a phase-separated structure is not limited to the above-described embodiment and may have steps (optional steps) in addition to step (i) and step (ii).

This optional step includes a step (hereinafter, referred to as “step (iii)”) of selectively removing a phase having at least one block of the block (b1) and the block (b2) constituting the (BCP) component of the BCP layer 3, a step of forming a guide pattern, and the like.

Regarding Step (iii)

In the step (iii), the phase having at least one block of the block (b1) and the block (b2) constituting the (BCP) component of the BCP layer formed on the undercoat agent layer 2 is selectively removed. As a result, a fine pattern (a polymer nanostructure) is formed.

As a method for selectively removing the phase having blocks, a method for performing oxygen plasma treatment on the BCP layer, a method for performing hydrogen plasma treatment and the like can be exemplified.

For example, by performing oxygen plasma treatment, hydrogen plasma treatment or the like on the BCP layer after the phase separation of the BCP layer including the (BCP) component, the phase having the block (b1) is not selectively removed and the phase having the block (b2) is selectively removed.

FIG. 2 shows an example of an embodiment of step (iii).

In the embodiment shown in FIG. 2, in a case where the phase 3a is selectively removed and a pattern (polymer nanostructure) from the separated phase 3b is formed by performing oxygen plasma treatment on the structure 3′ produced on the support 1 in step (ii), the phase 3b is a phase having the block (b1) and the phase 3a is a phase having the block (b2).

The support 1 having the patterns formed by the phase separation of the BCP layer 3 having the (BCP) component as described above can be used as it is, but the shape of the patterns (polymer nanostructure) of the support 1 may be changed by further heating.

The temperature condition for heating is preferably equal to or higher than the glass transition temperature of the block copolymer to be used and is preferably lower than the thermal decomposition temperature. In addition, the heating is preferably performed in a gas having low reactivity such as nitrogen.

### Regarding Guide Pattern Forming Step

In the method for producing a structure including a phase-separated structure, a step (guide pattern forming step) of forming a guide pattern on the undercoat agent layer may be provided between the above-described step (i) and step (ii). This makes it possible to control the array structure of the phase-separated structures.

For example, even with respect to a block copolymer in which a random fingerprint-shaped phase-separated structure is formed in a case where the guide pattern is not provided, a phase-separated structure oriented along the groove can be obtained by providing a groove structure of a resist film on the surface of the undercoat agent layer. According to such a principle, a guide pattern may be provided on the undercoat agent layer 2. Further, in the case where the surface of the guide pattern has an affinity with any of the blocks constituting the (BCP) component, a phase-separated structure having a cylinder structure oriented in the direction perpendicular to the surface of the support is likely to be formed.

The guide pattern can be formed using, for example, a resist composition.

As the resist composition for forming the guide pattern, generally, those having the affinity with any of the blocks constituting the (BCP) component can be appropriately selected for use from the resist compositions used for forming resist patterns or modified products thereof. The resist composition may be any of a positive-type resist composition for forming a positive-type pattern in which the exposed area of the resist film is dissolved and removed and a negative-type resist composition for forming a negative-type pattern in which the unexposed area of the resist film is dissolved and removed, and the composition is preferably a negative-type resist composition. As the negative-type resist composition, for example, a resist composition including an acid generator, and a base material component in which the solubility in a developing solution including an organic solvent by the action of an acid is decreased by the action of an acid, and the base material component includes a resin component having a constituent unit which is decomposed by the action of an acid to increase the polarity is preferable.

After the BCP composition is poured on the undercoat agent layer on which the guide pattern is formed, an annealing treatment is performed to cause phase separation. Therefore, as the resist composition for forming the guide pattern, it is preferable that the composition can form a resist film excellent in solvent resistance and heat resistance can be formed.

### EXAMPLES

Hereinafter, the invention will be described in more detail with reference to examples, but the invention is not limited to the following examples.

### Synthesis Example of Block Copolymer (1)

1 g (2.38 mmol) of a block copolymer (PS-b-PMMA) (Mn=42,000, styrene ratio of 50 mass %) of styrene and methyl methacrylate, 0.72 mL (11.9 mmol) of ethanolamine, 1.5 mL of diglyme and 1.5 mL of dimethyl sulfoxide were added into a flask having a volume of 20 mL and stirred, and the reaction was carried out at 120° C. for 6 hours in a nitrogen atmosphere. Subsequently, the solvent was removed under reduced pressure, and the resulting residue was poured in methanol to obtain 130 mg of a block copolymer (1) as white powder.

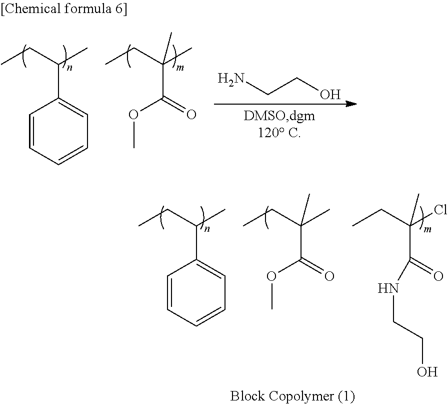

### Synthesis Example of Block Copolymers (2) to (6)

The block copolymers (2) to (6) were obtained by carrying out the polymerization in the same manner as in Synthesis Example (1) of the block copolymer except that the blending amount of styrene, the blending amount of methyl methacrylate, and the polymerization time were changed respectively.

The polymerization time (h) for the obtained block copolymers (1) to (6), the proportion (mol %) of the constituent units represented by general formula (h1) in the block copolymer, the weight average molecular weight (Mw) in terms of standard polystyrene determined by GPC measurement and the molecular weight distribution (Mw/Mn) were shown in Table 1.

TABLE 1

| | | Proportion | | |
|---|---|---|---|---|
| | | (mol %) of the | | |
| | | Constituent | Weight | |
| | | Units | Average | Molecular |
| | Polymerization | Represented | Molecular | Weight |
| | Time | by general | Weight | Distribution |
| | (h) | formula (h1) | (Mw) | (Mw/Mn) |
| Block | 6 | 4 | 42,000 | 1.02 |
| Copolymer | | | | |
| (1) | | | | |
| Block | 18 | 18 | 28,000 | 1.02 |
| Copolymer | | | | |
| (2) | | | | |
| Block | 12 | 5 | 28,000 | 1.02 |
| Copolymer | | | | |
| (3) | | | | |
| Block | 6 | 1 | 28,000 | 1.02 |
| Copolymer | | | | |
| (4) | | | | |
| Block | 18 | 8 | 20,000 | 1.02 |
| Copolymer | | | | |
| (5) | | | | |
| Block | 6 | 1 | 20,000 | 1.02 |
| Copolymer | | | | |
| (6) | | | | |

### Preparation of Resin Composition

The respective components shown in Table 2 were mixed and dissolved to prepare a resin composition (solid content concentration of 0.8 mass %).

TABLE 2

| | | Organic Solvent |
|---|---|---|
| Resin Composition | Block Copolymer | Component |
| Resin Composition (1) | BCP-1 | (S)-1 |
| | [100] | [12400] |
| Resin Composition (2) | BCP-2 | (S)-1 |
| | [100] | [12400] |
| Resin Composition (3) | BCP-3 | (S)-1 |
| | [100] | [12400] |
| Resin Composition (4) | BCP-4 | (S)-1 |
| | [100] | [12400] |
| Resin Composition (5) | BCP-5 | (S)-1 |
| | [100] | [12400] |
| Resin Composition (6) | BCP-6 | (S)-1 |
| | [100] | [12400] |

Each of the abbreviations in Table 2 has the following meanings. The numerical values in the brackets were the blending amount (parts by mass).

BCP-1: The block copolymer (1)

BCP-2: The block copolymer (2)

BCP-3: The block copolymer (3)

BCP-4: The block copolymer (4)

BCP-5: The block copolymer (5)

BCP-6: The block copolymer (6)

(S)-1: Propylene glycol monomethyl ether acetate.

### Test Examples 1 to 6

### Production of Structure Including Phase-Separated Structure

A structure including a phase-separated structure was obtained by using the resin compositions (1) to (6) according to the production method including the following step (i) and step (ii).

In addition, the production methods of Test Examples 5 to 6 were those to which the invention is applied.

### Step (i):

On the Si substrate on which the organic film was formed, the resin composition of each example was spin-coated so as to have a film thickness of 20 nm, thereby forming a resin composition layer (layer including a block copolymer).

### Step (ii):

The resin composition layer formed on the Si substrate was baked at 240° C. for 60 seconds to form a phase-separated structure.

Step (iii):

Oxygen plasma treatment (200 mL/min, 40 Pa, 40° C., 200 W, 20 seconds) was performed on the Si substrate on which the phase-separated structure was formed by using TCA-3822 (manufactured by TOKYO OHKA KOGYO CO., LTD.) and thus PMMA phase was selectively removed.

### Measurement by X-Ray Small Angle Scattering (SAXS) Method

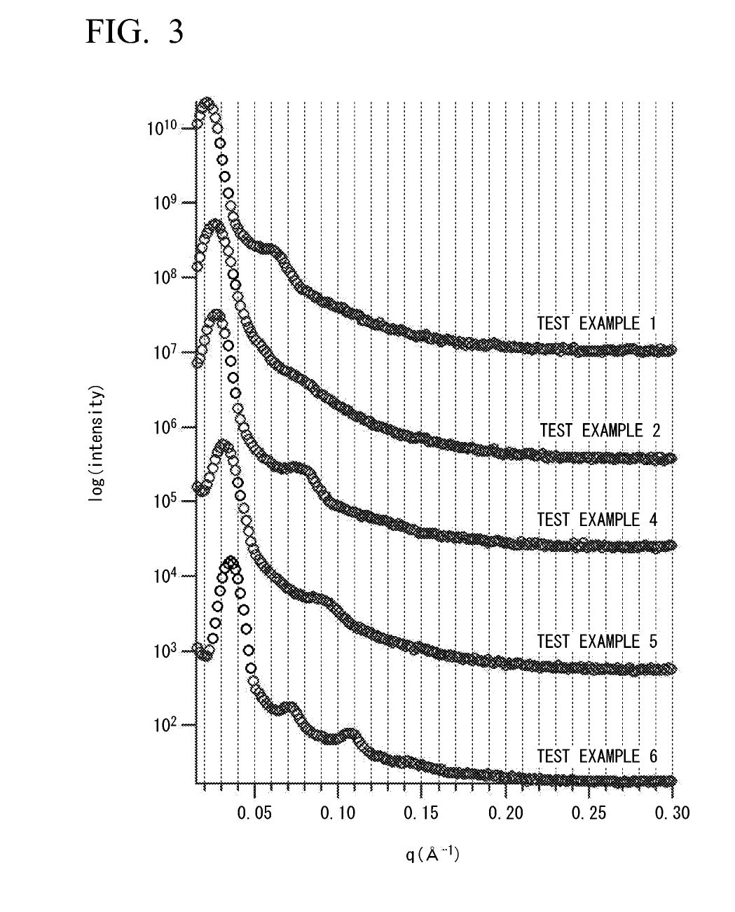

The measurement was carried out by X-ray small angle scattering (SAXS) method. The measurement results were shown in FIG. 3.

FIG. 3 is a diagram showing X-ray small angle scattering (SAXS) patterns for a phase-separated structure formed by using the resin composition of each example. The period (nm) of the structure was determined at the first scattering peak of the SAXS pattern curve. The results were shown in Table 3.

In the production methods of Test Examples 1 to 6, the periodic structure of Lamella was confirmed in any of the examples.

### Evaluation of Phase Separation Performance

The surface (phase-separated state) of the obtained substrate was observed with a scanning electron microscope SEM (SU8000, manufactured by Hitachi High-Technologies Corporation).

As a result of such observation, a pattern in which a vertical cylinder pattern was observed was designated as A, a pattern in which a vertical cylinder shape and a horizontal cylinder shape were mixed was designated as B, a pattern in which the horizontal cylinder was observed was designated as C, and a pattern in which data were not obtained is designated as -. Accordingly, the results were shown in Table 3 as “Phase Separation Performance”

TABLE 3

| | | Period | Phase Separation |
|---|---|---|---|
| | Resin Composition | (nm) | Performance |
| Test Example 1 | Resin Composition (1) | 29.0 | A |
| Test Example 2 | Resin Composition (2) | 24.1 | A |
| Test Example 3 | Resin Composition (3) | 24.0 | — |
| Test Example 4 | Resin Composition (4) | 23.5 | A |
| Test Example 5 | Resin Composition (5) | 19.4 | A |
| Test Example 6 | Resin Composition (6) | 17.7 | A |

From the results shown in Table 3, it can be confirmed that the use of the resin composition of Test Examples 5 and 6 to which the present invention is applied can further improve the phase separation performance without requiring a new monomer.

What is claimed is:

1. A method for producing a structure including a phase-separated structure, comprising:
applying a resin composition on a support to form a layer including a block copolymer; and
phase-separating the layer including the block copolymer,
wherein the resin composition comprises a block copolymer having a block (b1) having a repeating structure of styrene units; a block (b2) having a repeating structure of methyl methacrylate units partially substituted with a constituent unit represented by the following general formula (h1); and a number average molecular weight of less than 28,000: 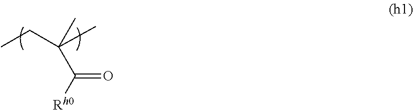
wherein R^{h0} is a hydrophilic functional group.

2. The method according to claim 1, wherein the molecular weight distribution of the block copolymer is 1.01 to 1.10.

3. The method according to claim 1, wherein R^{h0} in general formula (h1) is a hydrophilic functional group derived from an amine.

4. The method according to claim 3, wherein R^{h0} in general formula (h1) is a functional group represented by the following general formula (R^{h0}-1): 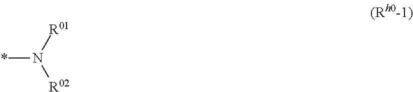
wherein R⁰¹ is an aliphatic hydrocarbon group having at least —OH as a substituent; R⁰² is an aliphatic hydrocarbon group which may have a substituent or a hydrogen atom; and * is a bonding site that bonds to the carbon atom of the carbonyl group in the formula (h1).

5. The method according to claim 4, wherein R⁰¹ in general formula (R^{h0}-1) is an alkyl group having 1 to 8 carbon atoms, having at least —OH as a substituent.

6. The method according to claim 5, wherein R⁰² in general formula (R^{h0}-1) is a hydrogen atom.

7. The method according to claim 6, wherein R^{h0} in general formula (h1) is a functional group represented by the following general formula (R^{h0}-1-1)

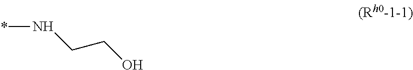

8. The method according to claim 1, wherein the proportion of the constituent unit represented by general formula (h1) in the block copolymer is 1 to 10 mol % with respect to the total constituent units constituting the block copolymer.

9. The method according to claim 2, wherein the proportion of the constituent unit represented by general formula (h1) in the block copolymer is 1 to 10 mol % with respect to the total constituent units constituting the block copolymer.

10. The method according to claim 3, wherein the proportion of the constituent unit represented by general formula (h1) in the block copolymer is 1 to 10 mol % with respect to the total constituent units constituting the block copolymer.

11. The method according to claim 4, wherein the proportion of the constituent unit represented by general formula (h1) in the block copolymer is 1 to 10 mol % with respect to the total constituent units constituting the block copolymer.

12. The method according to claim 5, wherein the proportion of the constituent unit represented by general formula (h1) in the block copolymer is 1 to 10 mol % with respect to the total constituent units constituting the block copolymer.

13. The method according to claim 6, wherein the proportion of the constituent unit represented by general formula (h1) in the block copolymer is 1 to 10 mol % with respect to the total constituent units constituting the block copolymer.

14. The method according to claim 7, wherein the proportion of the constituent unit represented by general formula (h1) in the block copolymer is 1 to 10 mol % with respect to the total constituent units constituting the block copolymer.
